(19) United States
(12) Patent Application Publication
(10) Pub. No.: US 2016/0003875 A1
(43) Pub. Date: Jan. 7, 2016

(54) ALTERNATING CURRENT DETECTOR

(71) Applicant: K-LINE AUTOMATION CO., LTD., New Taipei City (TW)

(72) Inventor: Gary YUAN, New Taipei City (TW)

(73) Assignee: K-LINE AUTOMATION CO., LTD., New Taipei City (TW)

(21) Appl. No.: 14/321,051

(22) Filed: Jul. 1, 2014

(51) Int. Cl. G01R 19/00

(52) U.S. Cl. CPC G01R 19/0092

(57) ABSTRACT

An alternating current detector is provided. The alternating current detector comprises a housing, a solenoid, a rectification and filtration circuit, an amplification and driving circuit. The housing has a penetration cavity in the middle thereof, and a wire loading an alternating current thereon passes through the penetration cavity. The solenoid surrounds the penetration cavity and detects a magnetic field generated by the alternating current to generate a first voltage. The rectification and filtration circuit rectifies and filters the first voltage to generate a second voltage. The amplification and driving circuit amplifies the second voltage to generate an output current between a first output terminal and a second terminal.

### CROSS-REFERENCE TO RELATED APPLICATION

This application claims priority of application No. 102126043, filed on Jul. 22, 2013 in the Taiwan Intellectual Property Office.

### FIELD OF THE INVENTION

The invention relates to alternating current, and more particularly to a detector for non-invasively detecting the level and quality of alternating current.

### BACKGROUND OF THE INVENTION

Alternating current (AC) is a current which periodically changes amperage and reverses direction, the average amperage of which is zero in a period. Compared with direct current (DC) of which direction does not reverse periodically, alternating current transmits electrical power more efficiently. Consequently, alternating current is the form in which electrical power is delivered to businesses and residences.

Because the electrical power of most electric appliances is supplied by alternating current, if the alternating current cannot be supplied of sufficient quality, most electric appliances cannot work normally and may be damaged. Consequently, how to detect whether the alternating current supplies electrical power normally is a solution to solve the problem.

With reference to FIG. 8, Taiwan Pat. No. M450732 discloses a block diagram of a voltage detector 800. The voltage detector 800 receives a waveform signal of an external alternating current source and compares an amplitude of the waveform signal of the external alternating current source with an amplitude of the waveform signal of a standby alternating current source. At the same time of the external alternating current source and the standby alternating current source, if the amplitude of the waveform signal of the external alternating current source is less than the amplitude of the waveform signal of the standby alternating current source, the voltage of the external alternating current source is lower and less than the rated voltage value of the standby alternating current source. Then a control unit switches a machine from being connected to the external alternating current source state to being connected to the standby alternating current source state. Consequently, the machine avoids shutdown according to a sudden drop in the voltage of the external alternating current source.

However, the alternating current detector is coupled to the alternating current itself. In the prior art of FIG. 8, the voltage detector 800 must be coupled to the external alternating current source to detect and compare the voltage of the external alternating current source to detect if the voltage drops. If the alternating current detector is coupled to the alternating current source, a loading on the alternating current source is added and consumption of electricity is increased.

Even though these disadvantages of the prior art are known, there have been no acceptable and easy solutions to solve the problem.

### SUMMARY OF THE INVENTION

One objective of the invention is to provide an alternating current detector. In one embodiment, the alternating current detector comprises a housing, a solenoid, a rectification and filtration circuit and an amplification and driving circuit. The housing has a penetration cavity in the middle thereof. A wire passes through the penetration cavity for loading an alternating current. The solenoid is located in the inside of the housing, surrounds the penetration cavity and detects a magnetic field generated by the alternating current on the wire to generate a first voltage. The rectification and filtration circuit is located in the inside of the housing, and rectifies and filters the first voltage to generate a second voltage. The amplification and driving circuit is located in the inside of the housing, and amplifies the second voltage to generate an output current between a first output terminal and a second terminal.

In order to accomplish the aforementioned objective, the invention provides an alternating current detector. In another embodiment, the alternating current detector comprises a magnetic field sensing circuit, a rectification and filtration circuit and an amplification and driving circuit. The magnetic field sensing circuit detects a magnetic field of a specified zone and generates a first voltage in a first node according the magnetic field, wherein a wire loading an alternating current generates the magnetic field in the specified zone. The rectification and filtration circuit is coupled to the first node and a second node, and rectifies and filters the first voltage to generating a second voltage in the second node. The amplification and driving circuit is coupled to the second node, and amplifies the second voltage to generate an output current between a first output terminal and a second output terminal.

The alternating current detector of the present invention directly detects the magnetic field which is generated by the alternating current in a noninvasive manner. Consequently, the alternating current detector is convenient for being installed in most electric appliances since the electric appliances do not need to be disassembled. Additionally, the alternating current detector of the present invention turns on the indicating lamp by the electric power which is generated by a magnetic field without an external electric source. Additionally, the alternating current detector of the present invention transforms a detected alternating current signal to a digitalized ON/OFF electronic signal, which does not interfere and can be detected over a long distance. Finally, multiple alternating current detectors of the present invention can be cascaded together to economize input terminals of the programmable logic circuit.

### BRIEF DESCRIPTION OF THE DRAWINGS

FIG. 1 is a front perspective view showing the alternating current detector of the present invention;

FIG. 2A is a perspective view showing the alternating current detector of the present invention;

FIG. 2B is a perspective view showing a magnetic field generated by the alternating current of the penetration cavity in the middle of the alternating current detector;

FIG. 3 is a perspective view showing the alternating current detector and a wire loading an alternating current;

FIG. 4 is a perspective view showing a relation between the output voltage of the alternating current detector and the root mean square value of alternating current;

FIG. 5 is a block diagram showing the alternating current detector of the present invention;

FIG. 6A is a perspective view showing an embodiment of the alternating current detector of the present invention connected to a programmable logic circuit;

FIG. 6B is a perspective view showing another embodiment of the alternating current detector of the present invention connected to a programmable logic circuit;

FIG. 7 is a perspective view showing an embodiment of multiple alternating current detector of the present invention connected to a programmable logic circuit; and

FIG. 8 is a block diagram showing a voltage detector of Taiwan Pat. No. M450732 of the prior art.

### DETAILED DESCRIPTION OF THE INVENTION

In order to describe details of the preferred embodiment of the present invention, description of the structure, and the application as well as the steps are made with reference to the accompanying drawings. It is learned that after the description, any variation, modification or the like to the structure and the steps of the embodiments of the preferred embodiment of the present invention is easily made available to any person skilled in the art. Thus, the following description is only for illustrative purpose only and does not, in any way, try to limit the scope of the present invention.

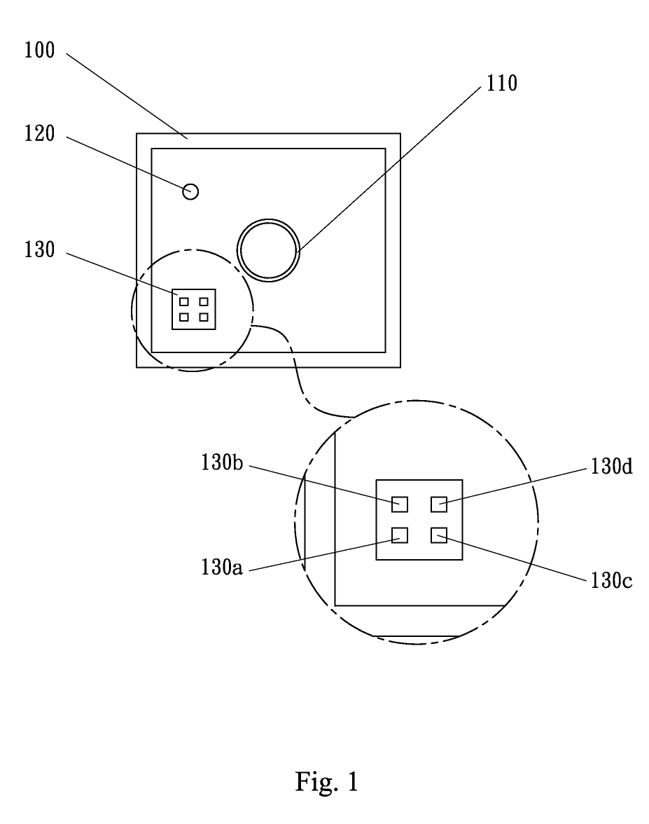

With reference to FIG. 1 of the preferred embodiment of the present invention, the front of an alternating current detector 100 constructed in accordance with the present invention comprises a penetration cavity 110 in the middle thereof. A wire passing through the penetration cavity 110 loads an alternating current. Also, the front of the alternating current detector 100 also comprises an indicating lamp 120. The alternating current detector 100 indicates whether the amplitude of the alternating current in the wire is at a normal level. If the amplitude of the alternating current in the wire is at a normal level, the indicating lamp 120 is turned on and illuminates. Conversely, if the amplitude of the alternating current in the wire is not at a normal level, the indicating lamp 120 is turned off. Consequently, a user can visually see if the amplitude of the alternating current in the wire is at a normal level by the ON/OFF state of the indicating lamp 120.

Additionally, the front of the alternating current detector 100 also comprises a pin set 130. In one embodiment, the pin set 130 comprises four pins 130a, 130b, 130c and 130d. The pins 130a and 130b are two output terminals of the alternating current detector 100. The alternating current detector 100 generates an output current between the pins 130a and 130b. When the alternating current in the wire is at a normal level, the output current between the pins 130a and 130b is equal to a first level. When the alternating current in the wire is not at a normal level, the output current between the pins 130a and 130b is equal to a second level. Consequently, a user can know whether the amplitude of the alternating current in the wire is at a normal level by an amperage of the output current which is generated by the alternating current detector 100.

In one embodiment, the pin set 130 further comprises pins 130c and 130d. The pin 130c is coupled to the pin 130d to be used by the alternating current detector 100 to cascade with a multiple number of alternating current detectors.

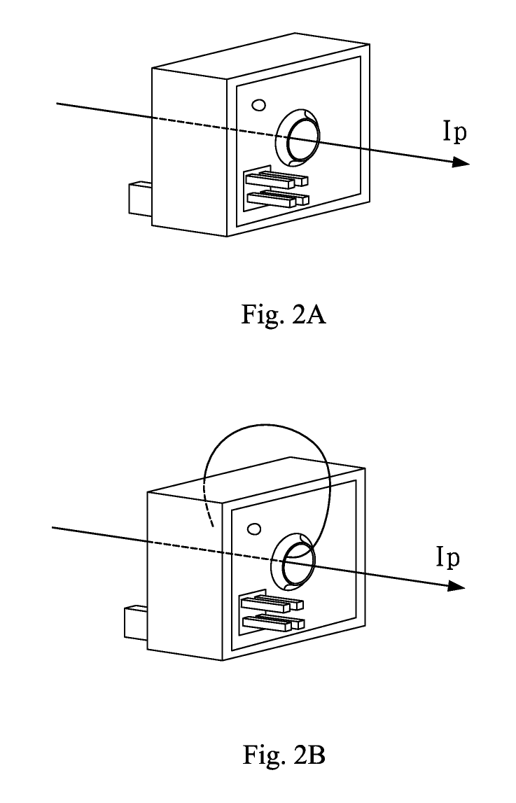

With reference to FIGS. 1 to 2B, a wire passing through a penetration cavity loads an alternating current. The wire is not coupled to an alternating current detector. Consequently, the alternating current detector is not be a load in the alternating current in the wire, so does not produce additional electric loss. The wire loads an alternating current Ip. When the alternating current Ip in the wire is varied, a magnetic field is generated around the wire, wherein the strength of the magnetic field is varied by the amplitude of the alternating current Ip. Consequently, the alternating current detector can determine the ON/OFF state of the indicating lamp 120 and the level of the output current by detecting the magnetic field around the penetration cavity.

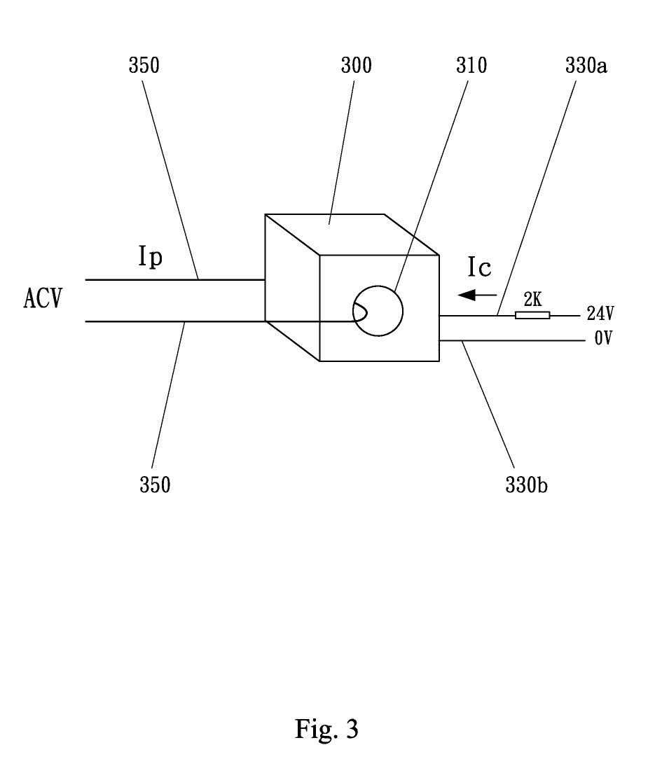

With reference to FIG. 3, the center of an alternating current detector 300 comprises a penetration cavity 310. A wire 350 loads an alternating current Ip thereon passing through the penetration cavity 310. Meanwhile, the alternating current detector 300 comprises two output terminals 330a and 330b. The alternating current detector 300 detects a magnetic field around the penetration cavity 310 to generate an output current between the output terminals 330a and 330b, wherein the magnetic field is generated by the alternating current Ip. In one embodiment, a loading resistance of the output terminals 330a and 330b is 2 KΩ, the output current passing the output terminals 330a and 330b is Ic, and the level of the output current Ic is [24V-0.8V]/2 K Ω.

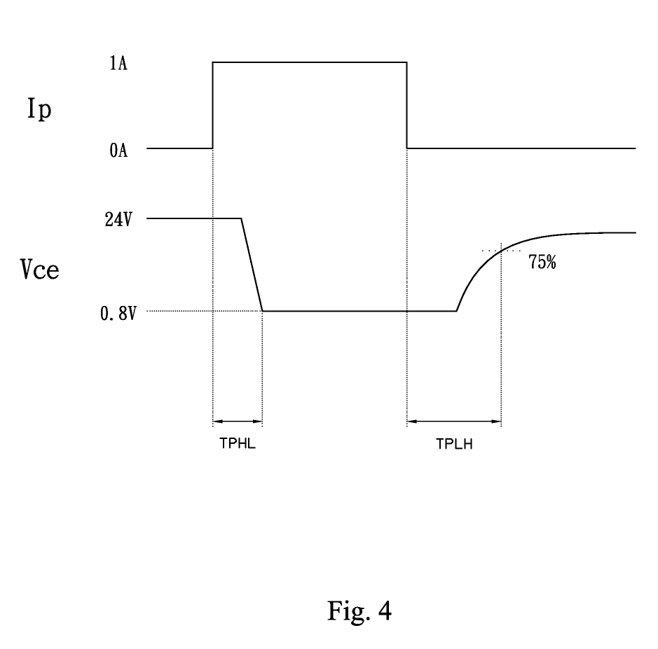

With reference to FIG. 4, an output voltage Vce of the alternating current detector comprises two levels. The first level is 0.8V, and the second level is 24V. When a root mean square value of the alternating current increases from 0 A to 1 A, then the output voltage Vce of the alternating current detector decreases from the second level 24V to the first level 0.8V in the time period TPHL. When the root mean square value of the alternating current decreases from 1 A to 0 A, then the output voltage Vce of the alternating current detector increases to 75% of a level from the first level 0.8V to the second level 24V in the time period TPLH. Consequently, the user can determine whether the alternating current Ip is at a normal level by the level of the output voltage Vce.

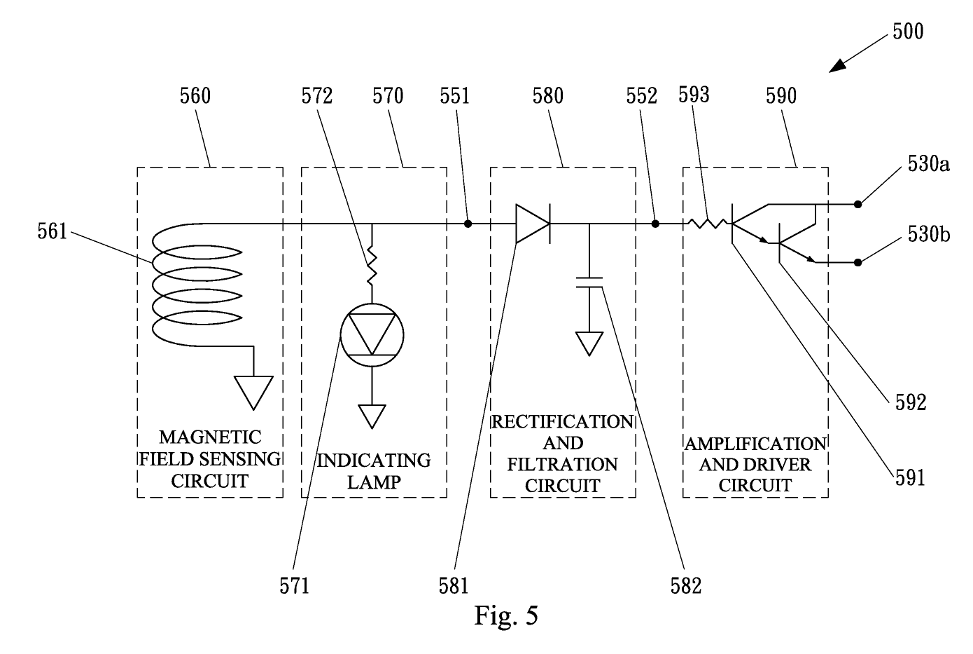

With reference to FIG. 5, in one embodiment, the alternating current detector 500 comprises a magnetic field sensing circuit 560, an indicating lamp 570, a rectification and filtration circuit 580 and an amplification and driving circuit 590. The magnetic field sensing circuit 560 detects a magnetic field of a specified zone and generates a first voltage in a first node 551 according to the magnetic field, wherein the specified zone is around a penetration cavity in the middle of a housing of the alternating current detector 500. In one embodiment, the magnetic field sensing circuit 560 comprises a solenoid 561 which detects a magnetic field generated by an alternating current on a wire around the penetration cavity. The indicating lamp 570 is coupled to the first node 551 and a ground potential, and emits light by the strength of the first voltage. In one embodiment, the indicating lamp 570 comprises a resistor 572 and an LED indicating lamp 571.

The rectification and filtration circuit 580 is coupled to the first node 551 and a second node 552, and rectifies and filters the first voltage to generate a second voltage in the second node 552. In one embodiment, The rectification and filtration circuit 580 comprises a diode 581 and a capacitor 582. The diode 581 is coupled to the first node 551 and the second node 552, which rectifies a current through the first node 551 and the second node 552. The capacitor 582 is coupled to the second node 552 and a ground potential. The amplification and driving circuit 590 is coupled to the second node 552, which amplifies the second voltage to generate an output current between a first output terminal 530a and a second output terminal 530b. In one embodiment, The amplification and driving circuit 590 comprises a first transistor 591, a resistor 593 and a second transistor 592. The first transistor comprises a collector which is coupled to the first output terminal 530a. The resistor 593 is coupled to a base of the first transistor 591 and the second node 552. The second transistor 592 comprises a base, a collector and an emitter. The base of the second transistor 592 is coupled to a emitter of the first transistor 591. The collector of the second transistor 592 is coupled to the first output terminal 530a. The emitter of the second transistor 592 is coupled to the second output terminal 530b.

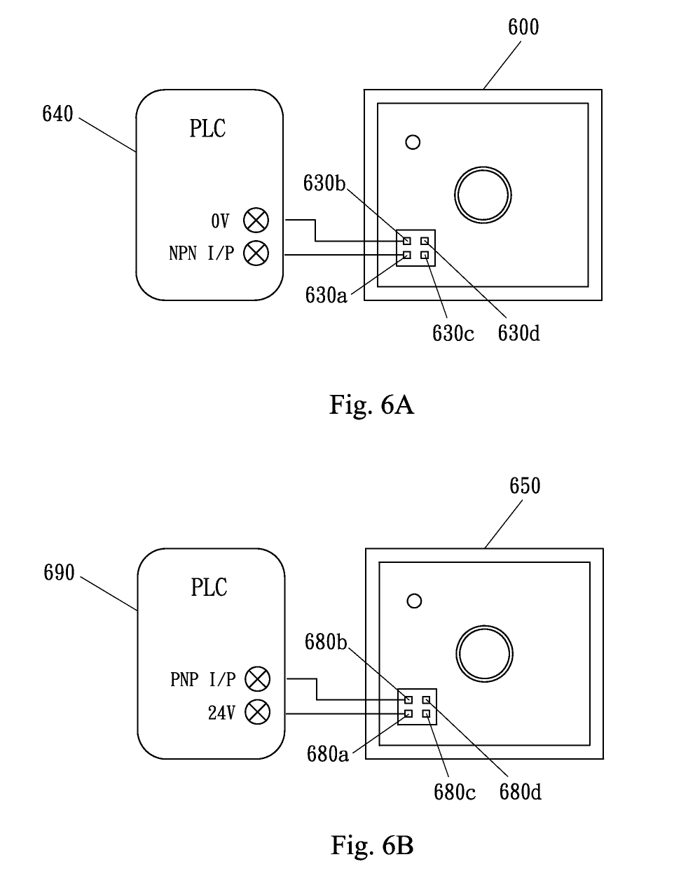

With reference to FIG. 6A, a first output terminal 630a of an alternating current detector 600 is coupled to an NPN I/P terminal of a programmable logic circuit 640. A second output terminal 630b of the alternating current detector 600 is coupled to a 0V terminal of the programmable logic circuit 640.

With reference to FIG. 6B, a first output terminal 680a of an alternating current detector 650 is coupled to a 24V terminal of a programmable logic circuit 690. A second output terminal 680b of the alternating current detector 650 is coupled to a PNP I/P terminal of the programmable logic circuit 690.

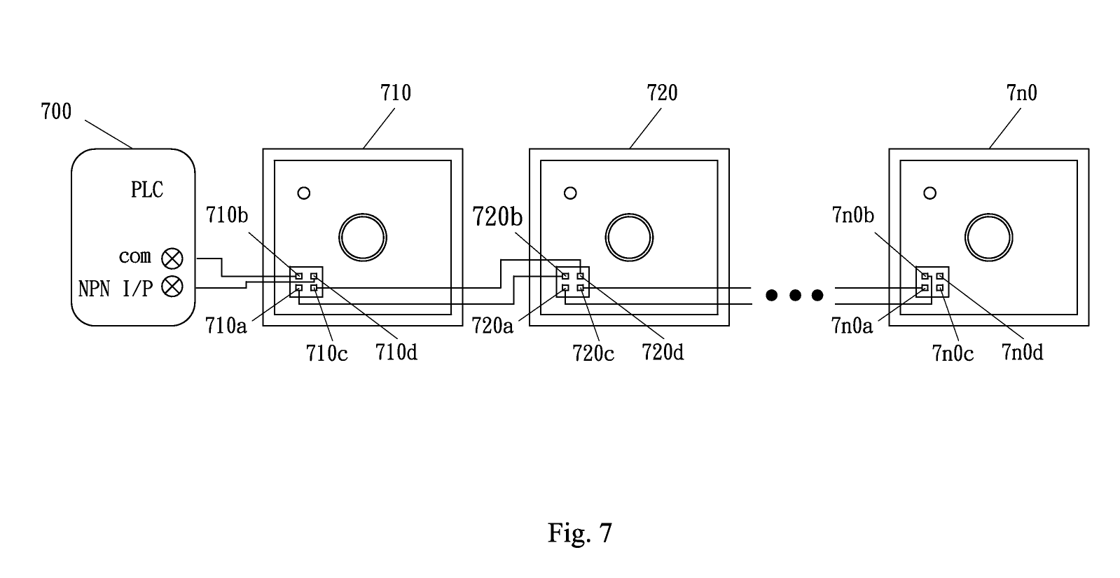

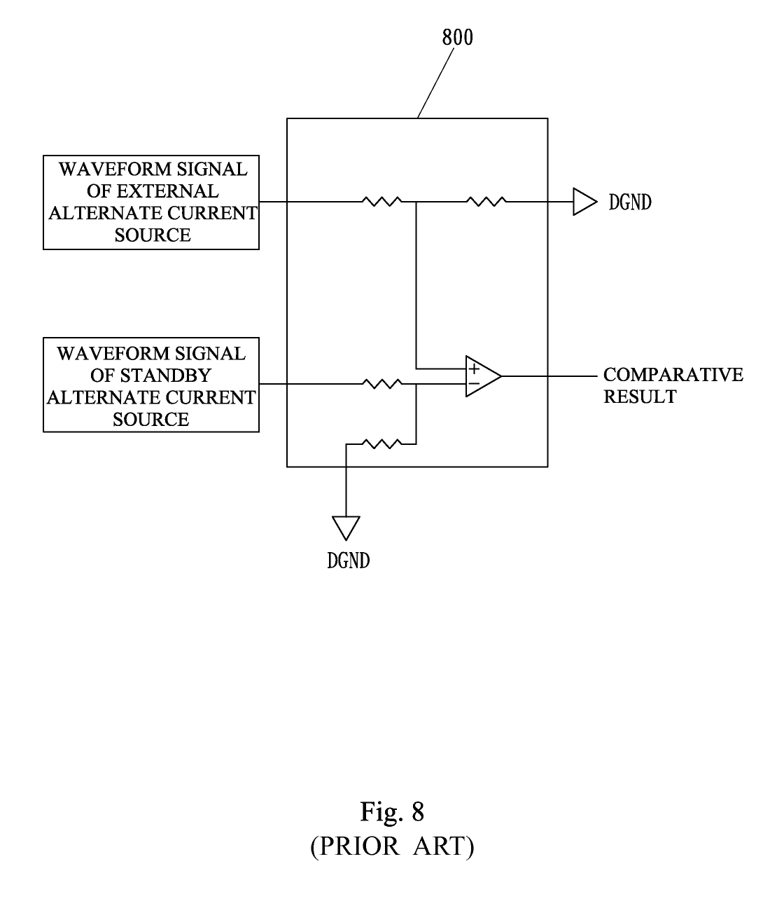

With reference to FIG. 7, when multiple alternating current detectors are cascaded together, except for the first and last alternating current detectors, the middle alternating current detectors have the same coupling method. For example, a second pin 720b of an alternating current detector 720 is coupled to a first pin 710a of a front alternating current detector 710. A fourth pin 720d of the alternating current detector 720 is coupled to a third pin 710c of the front alternating current detector 710. A first pin 720a of the alternating current detector 720 is coupled to a second pin 730b of a rear alternating current detector 730. A third pin 720c of the alternating current detector 720 is coupled to a fourth pin 730d of a rear alternating current detector 730.

Additionally, a first pin 7n0a of the last alternating current detector 7n0 is coupled to a third pin 7(n−1)0c of a front alternating current detector 7(n−1)0. A second pin 7n0b of the last alternating current detector 7n0 is coupled to a first pin 7(n−1)0a of a front alternating current detector 7(n−1)0. A first pin 710a of a first alternating current detector 710 is coupled to a com terminal of a front programmable logic circuit 700. A fourth pin 710d of the first alternating current detector 710 is coupled to an NPN I/P terminal of the front programmable logic circuit 700. Consequently, the output voltage of the multiple alternating current detectors 710, 720, . . . and 7n0 are summed and bridged over a second pin 710b and the fourth pin 710d of the first alternating current detector 710, so the front programmable logic circuit 700 only needs to be coupled to the first second pin 710b and the fourth pin 710d of the first alternating current detector 710 to detect all of the multiple alternating current detectors 710, 720, . . . and 7n0 to detect whether the electrical power is being supplied normally.

The alternating current detector of the present invention directly and non-invasively detects the magnetic field generated by alternating current. Consequently, the alternating current detector is convenient for being installed in most electric appliances, wherein the electric appliances do not need to be disassembled. Also, the alternating current detector of the present invention lights the indicating lamp by the electric power which is generated by a magnetic field without an external electric source. Additionally, the alternating current detector of the present invention transforms a detected alternating current signal to a digitalized ON/OFF electronic signal, which does not interfere and can be detected over a long distance. Finally, multiple alternating current detector of the present invention can be cascaded together to economize input terminals of the programmable logic circuit.

While the invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. An alternating current detector having a first output terminal and a second output terminal comprising:
a solenoid detecting a magnetic field of a specified zone and generating a first voltage in a first node according to the magnetic field, wherein a wire loading an alternating current generates the magnetic field in the specified zone;
a rectification and filtration circuit coupled to the first node and a second node, rectifying and filtering the first voltage to generating a second voltage; and
an amplification and driving circuit coupled to the second node, amplifying the second voltage to generate an output current between the first output terminal and the second output terminal.

2. The alternating current detector as claimed in claim 1, further comprising an indicating lamp which is coupled to the first node and a ground potential and emits light according to the first voltage.

3. The alternating current detector as claimed in claim 1, wherein the rectification and filtration circuit comprises:
a diode coupled to the first node and the second node and rectifying a current through the first node and the second node; and
a capacitor coupled to the second node and a ground potential.

4. The alternating current detector as claimed in claim 1, wherein the amplification and driving circuit comprises:
a first transistor comprising a collector coupled to the first output terminal;
a resistor coupled to a base of the first transistor and the second node;
a second transistor comprising
a base coupled to a emitter of the first transistor;
a collector coupled to the first output terminal; and
an emitter coupled to the second output terminal.

5. The alternating current detector as claimed in claim 1, wherein the alternating current detector outputs the output current to a programmable logic circuit via the first output terminal and the second output terminal.

6. The alternating current detector as claimed in claim 1, wherein the alternating current detector comprises a housing which comprises a first pin and a second pin, the first pin is coupled to the second pin, when the alternating current detector cascades a front alternating current detector and a rear alternating current detector, the first output terminal of the alternating current detector is coupled to a second output terminal of the rear alternating current detector, the second output terminal of the alternating current detector is coupled to a first output terminal of the front alternating current detector, the first pin of the alternating current detector is coupled to a second pin of the rear alternating current detector, the second pin of the alternating current detector is coupled to a first pin of the rear alternating current detector.

7. An alternating current detector comprising:
a housing comprising:
a penetration cavity in the middle of the housing, wherein a wire loading an alternating current thereon passes through the penetration cavity;
a first output terminal and
a second output terminal;
a solenoid located in the inside of the housing, surrounding the penetration cavity and detecting a magnetic field generated by the alternating current on the wire to generate a first voltage,
a rectification and filtration circuit rectifying and filtering the first voltage to generate a second voltage; and
an amplification and driving circuit amplifying the second voltage to generate an output current between the first output terminal and the second terminal.

8. The alternating current detector as claimed in claim 7, further comprises an indicating lamp coupled to the solenoid and emits light according to the first voltage.

9. The alternating current detector as claimed in claim 7, wherein the alternating current detector outputs the output current to a programmable logic circuit via the first output terminal and the second output terminal.

10. The alternating current detector as claimed in claim 7, wherein the housing comprises a first pin and a second pin, the first pin is coupled to the second pin, when the alternating current detector cascades a front alternating current detector and a rear alternating current detector, the first output terminal of the alternating current detector is coupled to a second output terminal of the rear alternating current detector, the second output terminal of the alternating current detector is coupled to a first output terminal of the front alternating current detector, the first pin of the alternating current detector is coupled to a second pin of the rear alternating current detector, the second pin of the alternating current detector is coupled to a first pin of the rear alternating current detector.
